(19) United States
(12) Patent Application Publication
(10) Pub. No.: US 2007/0210306 A1
(43) Pub. Date: Sep. 13, 2007

(54) TEST PATTERN FOR MEASURING CONTACT SHORT AT FIRST METAL LEVEL

(75) Inventors: Joyce E. Molinelli Acocella, Poughquag, NY (US); Oh-jung Kwon, Hopewell Junction, NY (US)

Correspondence Address: LAW OFFICE OF DELIO & PETERSON, LLC., 121 WHITNEY AVENUE, NEW HAVEN, CT, 06510, US

(73) Assignee: INTERNATIONAL BUSINESS MACHINES CORPORATION, Armonk, NY (US)

(21) Appl. No.: 11/308,137

(22) Filed: Mar. 8, 2006

(51) Int. Cl. H01L 23/58

(52) U.S. Cl. 257/48

(57) ABSTRACT

The invention relates to a test structure and methods of detecting electrical defects between adjacent metal contacts using such test structure at the first metal level within a semiconductor device. The test structure includes dual first metal level comb structures each having extending lines that are in direct electrical communication with contacts residing in the semiconductor. The extending lines of the first metal comb are interlaced with extending lines on the second metal comb such that adjacent metal contacts are in electrical communication with different metal combs. In this manner, upon testing for electrical continuity, an electrical current passing from the first metal comb to the second metal comb indicates an electrical defect existing between adjacent metal contacts.

### BACKGROUND OF THE INVENTION

1. Field of the Invention

This invention relates to semiconductor manufacturing and, in particular, to test structures or defect monitors at the first metal level within a semiconductor device for diagnosing contact shorts, and methods of forming the same.

2. Description of Related Art

In the manufacture of semiconductors, processing induced defects, which result in physical defects within the semiconductor product, continue to be a problem. Exemplary of processing induced defects that cause circuit failure are open circuits in conductive lines and short circuits between adjacent conductive lines.

With the improvements in lithographic imaging processes, a semiconductor wafer may be provided with increasingly fine features that allow for smaller device dimensions and higher density devices. However, these features are often smaller than the wavelength of light used to transfer the pattern onto the wafer. As such, as features become increasingly smaller, it has become increasingly more difficult to accurately transfer the pattern onto the wafer.

Conventional approaches aimed at solving the above problem include the use of phase-shifted masks and assist features on the mask. Phase-shifted masks selectively alter the phase of the light transmitted through the mask in order to improve the resolution of the features on the wafer. Assist features, by contrast, are used to pattern isolated high aspect features by nesting these otherwise isolated features in order to take advantage of photoresist and tools which are optimized to pattern nested features.

Another approach for minimizing process induced defects has been through the use of fabricating test structures during the integrated circuit manufacturing process. These test structures serve to yield reliability data on the regular product circuits. The principal reason for this is that the integrated circuits themselves cannot be probed because the interconnections in the device are neither accessible electrically, nor can the regions be isolated from one another to provide accurate data. The typical monolithic integrated semiconductor circuit involves such a dense pattern of impurity regions and metallurgy interconnecting them that the components cannot be readily isolated for testing purposes. Thus, semiconductor designers have found it necessary to design test structures isolated from the production circuits and which structures can be tested.

One manufacturing approach is the fabrication of defect monitors on the same wafers on which the actual semiconductor devices are fabricated. In this manner, the defect monitors are fabricated under the same processing environment and at the same time as the actual semiconductor devices, such that, these defect monitors more accurately replicate the processing induced defects in the actual products.

These defect monitors are typically fabricated within the kerf or discardable portion of the semiconductor wafer, and may include a metal serpentine line, one or more interdigitated metal lines, and/or one or more metal combs. As for the serpentine metal line, electrical continuity is checked whereby if a current cannot flow through the serpentine line, then an indication is made that the serpentine line is broken. Electrical continuity is also checked between the interdigitated metal lines and/or one or more metal combs, whereby if a current can flow between such lines or combs, then this implies that there is bridging (or shorting) across the gap where there should not be any conductors.

The simplistic design of most electrical defect process monitors, however, samples only a fraction of the design space and process development, and often does not provide an exact location of where the actual defects reside within the semiconductor wafer. In particular, current electrical defect monitors may be able to test for and locate defects in the contact array region of the device, however, they do not precisely pin-point exactly where these electrical defects reside within such region. That is, typical defect test monitors are limited to locating an electrical defect within the contact array region, whereby the located defect may reside between two adjacent contacts, between two adjacent metal lines residing above the contacts, or even between two adjacent polysilicon lines residing below the contacts. As such, once an electrical defect is located within this region of the wafer, it is often necessary to use non-electrical methods, such as physical examination, for locating exactly where the electrical defect resides in the wafer. Not only are these conventional electrical defect detection methods extremely time consuming, but they also do not isolate contact-to-contact shorts from the variety of other types of electrical defects residing within this region of the wafer.

Thus, while current test structures may be useful for limited purposes, there is still a need in the art for improved and more reliable test structures that will enhance the efficiency of the semiconductor manufacturing process, and in particular, will quickly and easily isolate contact-to-contact shorts from various other electrical defects within a wafer.

### SUMMARY OF THE INVENTION

Therefore, methods of forming a test pattern in a semiconductor device are disclosed which solve the above problems.

Bearing in mind the problems and deficiencies of the prior art, it is therefore an object of the present invention to provide methods and electrical defect test structures at the first metal level within a semiconductor device for diagnosing contact shorts.

It is another object of the present invention to provide methods and electrical defect test structures at the first metal level within a semiconductor device for distinguishing contact-to-contact shorts from various other electrical defects within a wafer.

A further object of the invention is to provide methods and electrical defect test structures that monitor contact shorts within a variety of types of materials and within a variety of geometric spacings of the semiconductor device components.

Still another problem is to provide methods and electrical defect test structures that provide enhanced manufacturing processes for quickly and easily locating contact short defects in the early stages of semiconductor fabrication.

Other objects and advantages of the invention will in part be obvious and will in part be apparent from the specification.

The above and other objects, which will be apparent to those skilled in art, are achieved in the present invention, which is directed to a test structure for testing for electrical continuity between adjacent contacts. The test structure includes gate conductors within an insulating layer over a substrate layer, and metal contacts within the insulating layer between adjacent gate conductors. Above these layers is a first metal comb structure having a first set of extending lines that are in electrical communication with a first set of the metal contacts within the insulating layer. A second metal comb structure is also above such layers. The second metal comb structure has a second set of extending lines that are interlaced with the first set of extending lines. The extending lines of the second metal comb structure are in electrical communication with a second set of the metal contacts. As such, each metal contact of the first set of contacts is adjacent to at least one metal contact of the second set of contacts, such that, an electrical current passing from the first metal comb structure to the second metal comb structure indicates an electrical defect existing between adjacent metal contacts.

In this aspect of the invention, the insulating layer may be a dielectric layer or a semiconductor layer that has sufficient insulating properties for electrically isolating the gate conductors from each other. The extending lines of the first and second metal comb structures may be straight extending metal lines in combination with straight electrically isolated gates, wiggled electrically isolated gates, or even in combination with first and second gate conductor comb structures having straight or wiggled interlaced extending gate conductor lines. Alternatively, the extending lines of the first and second metal comb structures may be wiggled extending metal lines in combination with straight electrically isolated gates, wiggled electrically isolated gates, first and second gate conductor comb structures having straight interlaced extending gate conductor lines, and/or first and second gate conductor comb structures having wiggled interlaced extending gate conductor lines.

In another aspect, the invention is directed to a method of detecting electrical defects between adjacent contacts using the test structures of the invention, as described herein. The method includes forming gate conductors over a substrate layer, insulating the gate conductors with an insulating material, and then providing metal contacts within the insulating layer between the gate conductors. First and second metal layer comb structures are then formed over the insulating layer. The first metal layer comb structure has a first set of extending lines in electrical communication with a first set of the metal contacts, while the second metal layer comb structure has a second set of extending lines in electrical communication with a second set of the metal contacts. These first and second sets of extending lines are formed such that they are interlaced with each other so that each metal contact of the first set of contacts is adjacent to at least one metal contact of the second set of contacts. An electrical continuity test is then performed using the first and second metal layer comb structures, whereby the detection of an electrical current passing from the first metal comb structure to the second metal comb structure indicates an electrical defect existing between adjacent contacts from the first and second sets of metal contacts.

### BRIEF DESCRIPTION OF THE DRAWINGS

The features of the invention believed to be novel and the elements characteristic of the invention are set forth with particularity in the appended claims. The figures are for illustration purposes only and are not drawn to scale. The invention itself, however, both as to organization and method of operation, may best be understood by reference to the detailed description which follows taken in conjunction with the accompanying drawings in which:

FIGS. 1A-10C illustrate top plan views, and cross sectional views, of processing steps of a first embodiment of the invention for forming dual metal comb structures at the first metal level within a semiconductor device for locating and distinguishing contact-to-contact shorts.

FIG. 11A illustrates a top perspective view of the semiconductor device of FIGS. 10A-10C having the dual metal comb structures residing over gate conductor comb structures.

FIGS. 11B and 11C illustrate cross sectional views of FIG. 11A across lines A-B and A′-B′, respectively.

FIGS. 12A-13C illustrate top plan views, and cross sectional views, of alternate processing steps of the invention for forming an alternate embodiment of the dual metal comb structures at the first metal level residing over isolated gate conductors within a semiconductor device.

FIG. 14A illustrates a top perspective view of the semiconductor device formed by the process steps of FIGS. 12A-13C.

FIGS. 14B and 14C illustrate cross sectional views of FIG. 14A across lines A-B and A′-B′, respectively.

### DESCRIPTION OF THE PREFERRED EMBODIMENT(S)

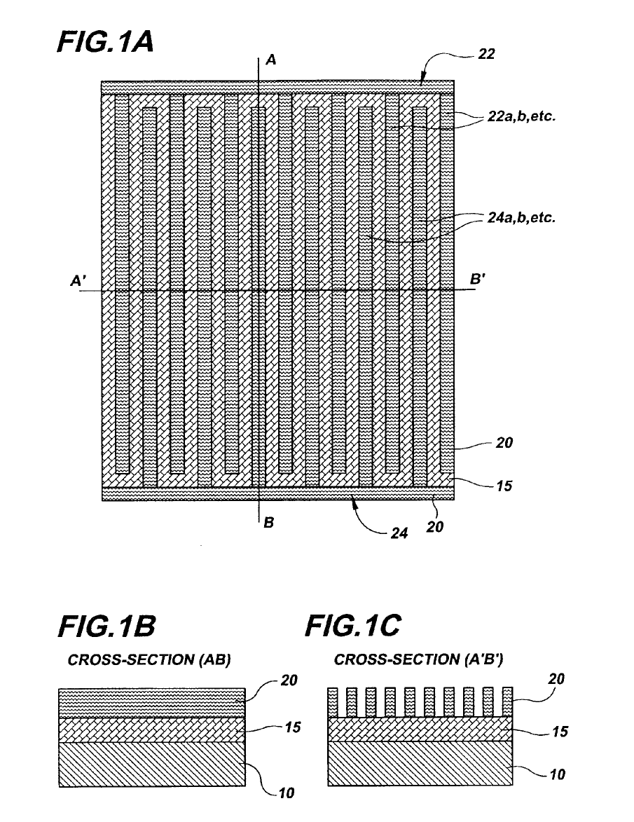

In describing the preferred embodiment of the present invention, reference will be made herein to FIGS. 1A-14C of the drawings in which like numerals refer to like features of the invention.

The invention is directed to electrical defect test structures at the first metal level within a semiconductor device for identifying and distinguishing contact-to-contact shorts from other types of electrical defects residing within the device. The present test structures advantageously detect contact-to-contact shorts early in the semiconductor development stages, thereby enhancing the manufacturing process and substantially eliminating contact-to-contact shorts in the final integrated circuit product.

Referring now to the drawings, FIGS. 1A-1C show a top plane view and cross sectional views along lines A-B and A′-B′ of a substrate 10, preferably a silicon substrate, having a pad nitride layer 15 deposited on a surface thereof. A photoresist layer 20 is deposited over the pad nitride layer 15, and is then patterned to form a dual comb structure 22, 24 each having interspaced comb lines 22 a, b, etc. and 24 a, b, etc., respectively. The photo resist layer 20 is patterned using conventional lithography techniques. The comb structures 22, 24 reside on opposite sides of the top surface of the pad nitride layer 15, whereby lines of each comb are interspaced such that each line on the first comb 22 is adjacent to lines on the second comb 24, and vice versa. That is, adjacent lines 22 a, b, etc on the first comb 22 are separated from each other by lines 24 a, b, etc. on the second comb 24, and vice versa. In this manner, neither comb structure, nor any part thereof, contacts the opposing comb structure, or any part thereof.

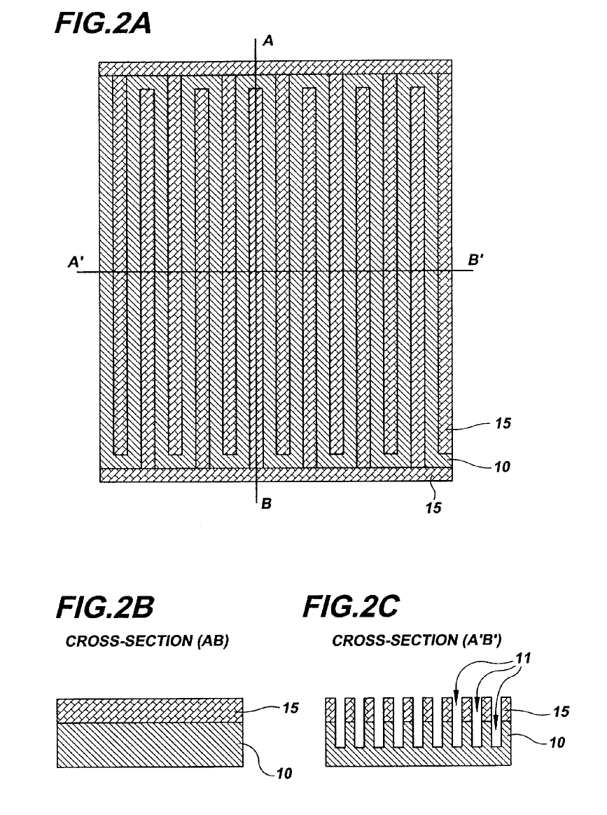

Referring to FIGS. 2A-2C, using the resist pattern as a mask, these comb patterns are then transferred through the pad nitride layer 15 and partially into the substrate layer 10. This step may be performed using conventional processing techniques including, for example, reactive ion etching using etch stop techniques for stopping the etch process within the substrate layer. In stopping the etch process within the substrate, openings 11 are provided in the pad nitride 15 and substrate 10 layers. Any remaining photo resist layer 20 is then removed from the structure surface, such as by resist stripping techniques. The openings within the substrate are preferably formed in the active area of the substrate.

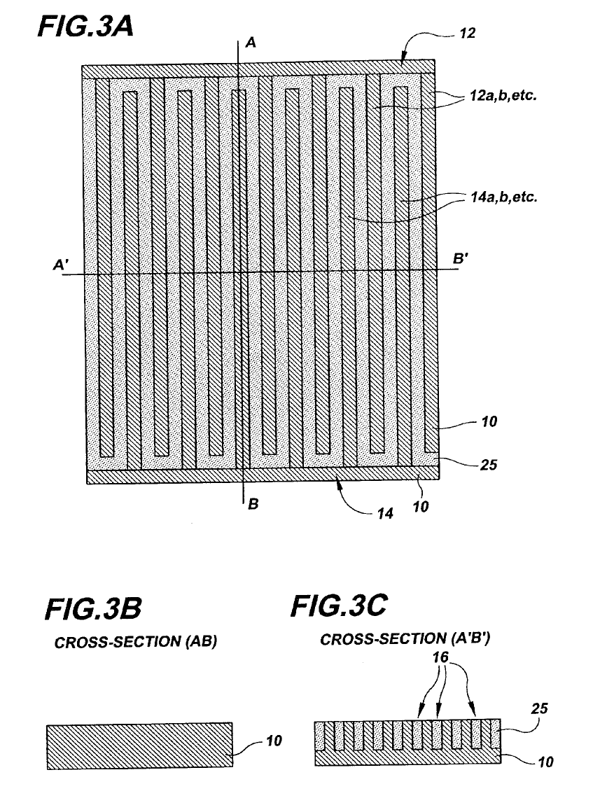

The openings 11 in the pad nitride 15 and substrate 10 layers are then filled with an insulating material, such as a dielectric material, using known techniques. The insulating material may include, but is not limited to, an oxide-based material 25 and the like. The structure is planarized down to a surface of the substrate layer 10 such that the pad nitride layer 15 is removed along with any insulating material residing in the pad nitride layer. In so doing, the substrate is provided with shallow trench isolation regions 16 as shown in FIGS. 3A-3C, and the comb pattern is transferred into the substrate layer to form dual substrate comb structures 12, 14 residing within the substrate 10. The structure may be planarized using conventional techniques, such as, by a chemical mechanical polishing followed by a pad nitride strip.

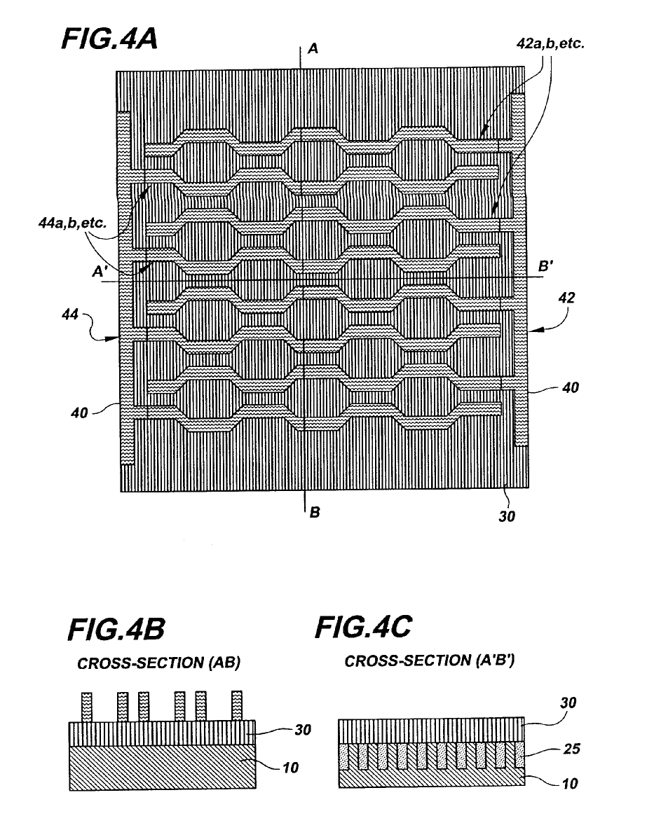

Next, gate oxidation, gate conductor deposition and lithography steps are performed for forming the gate conductors on the substrate layer 10. A thin gate oxide layer (not shown) is grown and then a polysilicon layer 30 is conformally deposited over the entire surface of the structure of FIGS. 3A-3C, followed by depositing a second photoresist layer 40 over the polysilicon layer 30. The resist layer 40 is patterned to form a second dual comb structure 42, 44 each having interspaced comb lines 42 a, b, etc. and 44 a, b, etc., respectively. The comb structures 42, 44 reside on opposite sides of the top surface of the polysilicon layer 30, such that the lines on opposing combs are interspaced with each other. This second set of dual comb structures 42, 44 is formed perpendicular to the dual substrate comb structures 12, 14. As shown in FIGS. 4A-4C, the lines of comb structures 42, 44 are each formed in a wiggled pattern for allowing more circuitry to be placed on the final semiconductor product, which is particularly beneficial for high density devices. However, as an alternative, it should be appreciated and understood that the lines may be formed as straight lines extending from each comb.

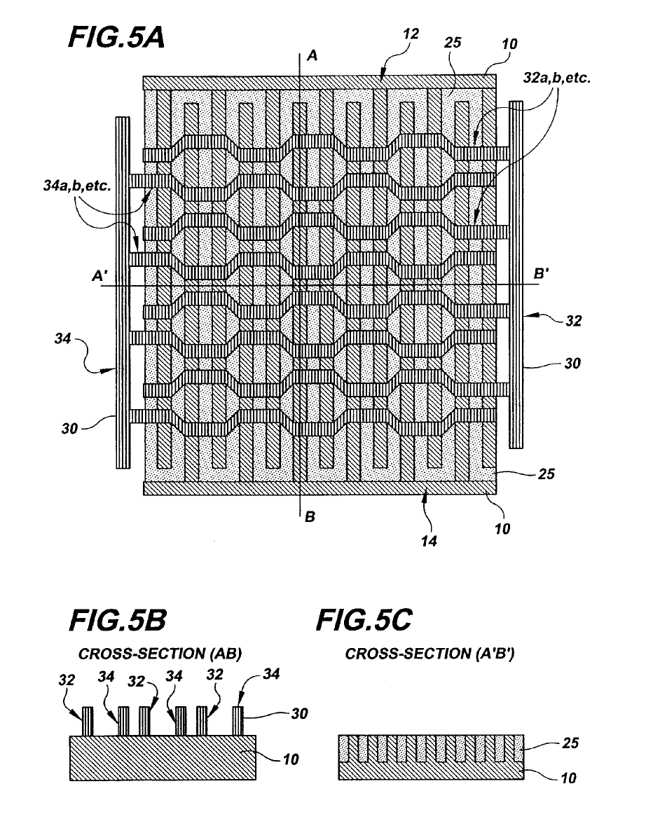

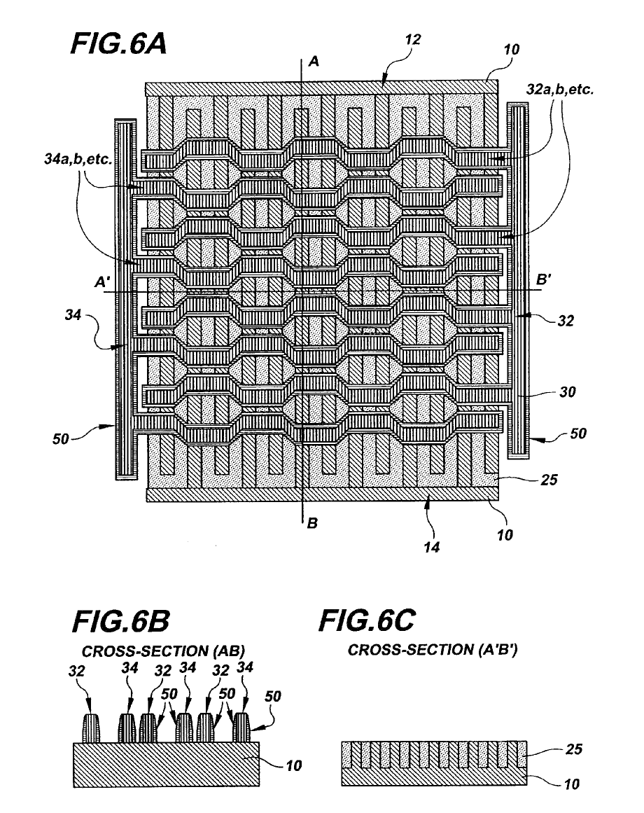

Referring to FIGS. 5A-5C and 6A-6C, using the patterned resist combs 42, 44 as a mask, the second dual comb structure is then transferred into the polysilicon layer 30 using conventional processing techniques including, for example, reactive ion etching using etch stop techniques for stopping the etch process on top of the substrate layer to form gate conductors as dual comb structures 32, 34 that reside perpendicular to the dual substrate comb structures 12, 14. These dual gate conductor comb structures have alternating extending lines 42 a, b, etc. and 44 a, b, etc. interspaced with each other. Any remaining photoresist layer 40 is then stripped, and optionally, spacers 50 may be formed along sidewalls of the dual comb gate conductor structures by known techniques. These spacers may consist of any suitable dielectric material including, but not limited to, nitride, oxide, and combinations thereof. For instance, the spacers may be formed by depositing a dielectric material, followed by reactive ion etching back the dielectric material to form spacers 50 along sidewalls of the gate conductors 32, 34.

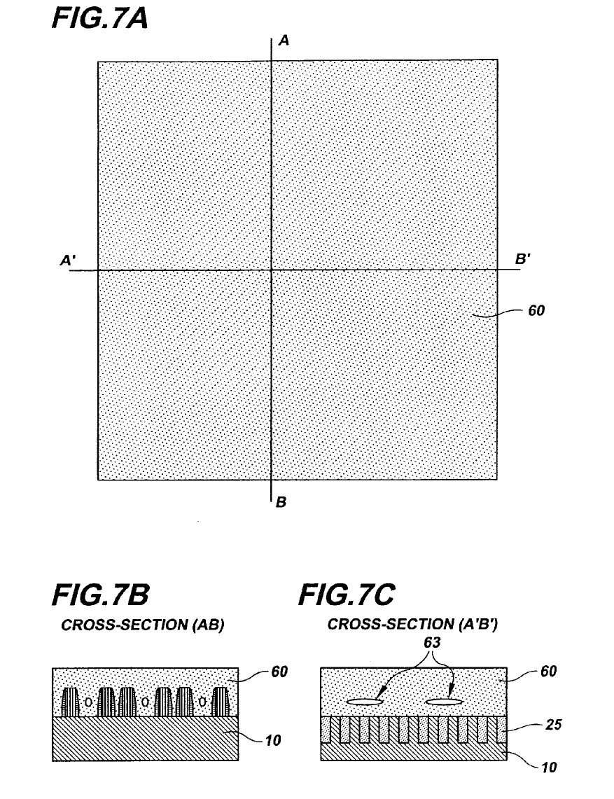

Once the gate conductors are formed, and optionally the dielectric spacers, a conformal insulating layer 60, such as a dielectric layer, is provided over the structure surface to cover the entire surface thereof. The insulating layer 60 may include, for example, an oxide based dielectric material, such as, borophosphosilicate glass (BPSG). However, during the process of providing this conformal insulating layer over the structure surface, voids 63 are sometimes formed within this insulating layer. These voids, or open regions, within the insulating layer typically reside, in this embodiment, across the isolation regions 25 between the gate conductor lines, as is shown in FIGS. 7A-7C.

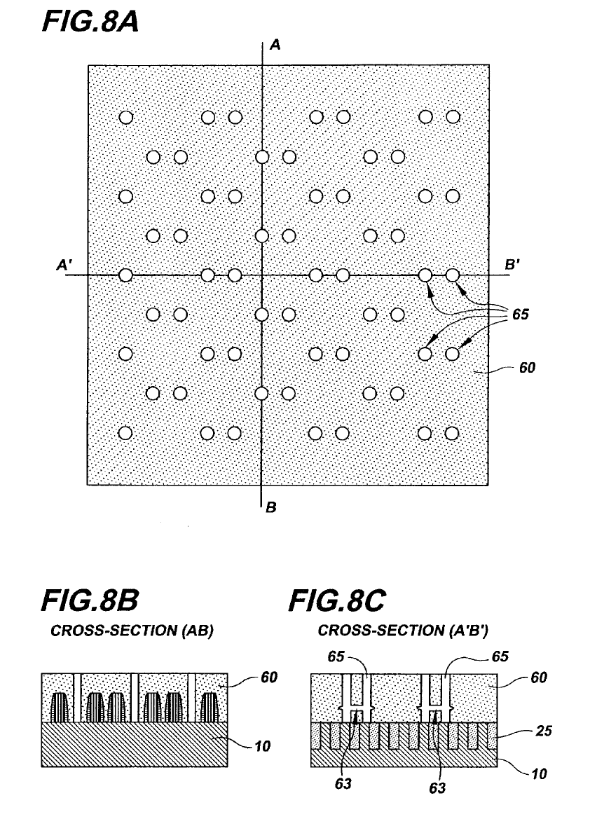

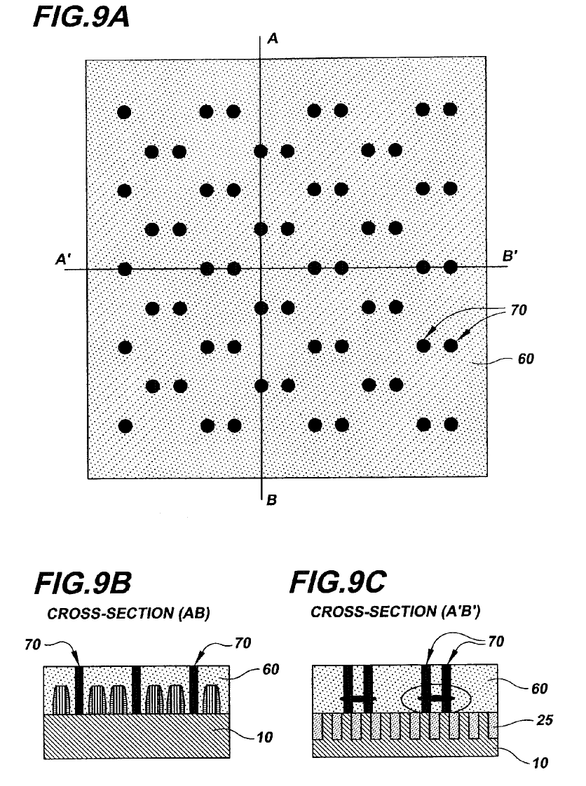

Referring to FIGS. 8A-8C, numerous contact openings 65 are then provided within the insulating layer 60. These openings 65 traverse vertically through the conformal insulating layer 60 down to a surface of the substrate layer 10, and are then filled with metallurgy by known techniques, followed by CMP, to form a plurality of contacts 70, as shown in FIGS. 9A-9C. However, in forming these openings 65, selected openings 65 traverse through the voids 63 such that a void may horizontally connect adjacent openings 65 to one another. In such an event, once the openings 65 are filled with metallurgy for forming the contacts, metal fills these horizontal voids 63 to cause a short between the adjacently connected contacts 70.

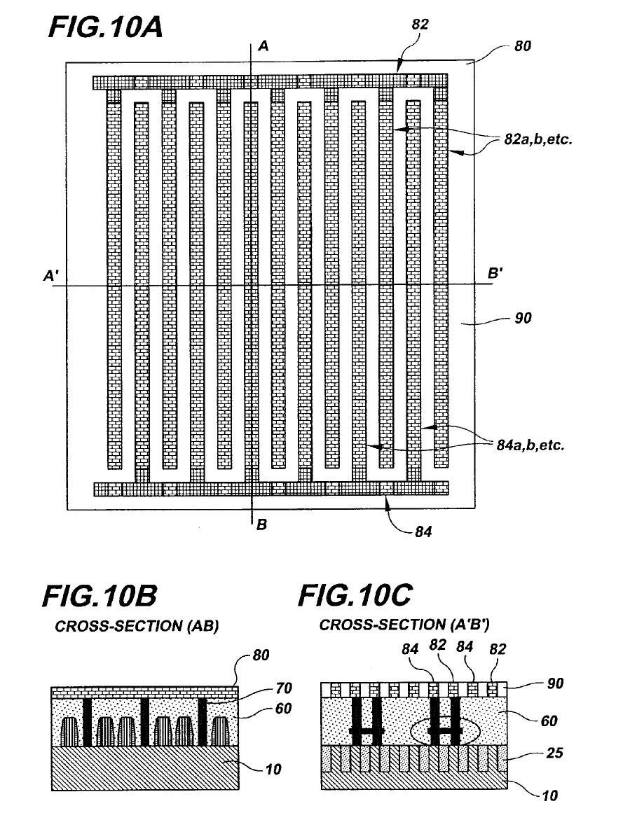

The invention provides a solution for testing for shorts between adjacent contacts early in the semiconductor development stage, and in particular, at the first metal level, also referred to herein as “M1”, within an IC having multiple metal layers. In accordance with the invention, a first level metal layer 80 is formed as a dual metal comb structure 82, 84 on a surface of the conformal insulating layer 60 in locations over the contacts 70, as shown in FIGS. 10A-10C.

Once the contacts 70 are formed in the insulating layer 60, the “M1” dual metal comb structures 82, 84 may be formed by a variety of processing techniques. In a first approach, the “M1” dual metal comb structures 82, 84 may be formed by depositing a metal layer over the planarized surface of layer 60, followed by a resist layer deposition. The resist layer is exposed and patterned via lithography to form dual comb resist structures, which are used as a mask to transfer such pattern into the underlying metal layer, such as by reactive ion etching. Any remaining resist layer is removed, another insulating material 90 (e.g., dielectric material) is then deposited to fill the openings residing between the dual comb metal structures 82, 84, followed by planarization of the structure surface to form the “M1” dual metal comb structures 82, 84. Insulating layers 60 and 90 may comprise the same material or different materials. As an alternative approach, the insulating material 90 may first be deposited over the planarized surface of insulating layer 60, followed by a resist deposition. The resist may then be patterned and exposed via lithography to form dual comb pattern openings in the insulating material 90, which are then filled with metal, and the structure planarized to form the “M1” dual metal comb structures 82, 84.

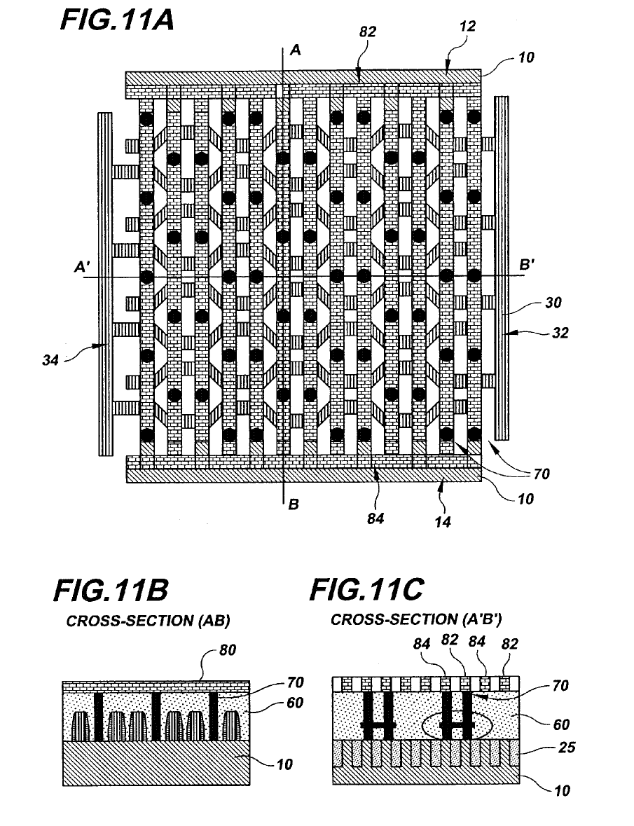

Referring to the top plane view of FIG. 10A, and the top perspective view of FIG. 11A, the “M1” dual metal comb structures 82, 84 are formed such that they reside on opposite sides of the top surface of the conformal insulating layer 60. The “M1” dual metal comb structures 82, 84 reside perpendicularly to the dual comb gate conductor structures 32, 34, and overlap the dual comb substrate structures 12, 14. Conductive lines (e.g., lines 82 a, b, etc. and lines 84 a, b, etc.) extend from each comb gate conductor such that these lines are electrically connected to one another, whereby such lines may be straight or wiggled. A wiggled gate conductor pattern makes it possible to measure a contact to gate conductor short caused by misalignment of the contact to the gate conductor. That is, lines 82 a, b, etc. on gate comb structure 82 are all electrically connected to one another, while lines 84 a, b, etc. on gate comb structure 84 are all electrically connected to one another. The extending lines 82 a, b, etc. of metal comb 82 and extending lines 84 a, b, etc. of metal comb 84 are interspaced with each other, and reside over the contacts 70 such that adjacent contacts reside under and are in direct communication with different metal comb structures.

In this manner, when testing for electrical continuity on the substrate at the first metal level, if a current can flow from one metal comb to the other, then this implies that there is an undesirable conductive line (i.e., a conductor) between at least one pair of contacts 70 that will short the final end product. In such an event, each pair of adjacent contacts 70 may then be checked for electrical continuity, whereby if a current can pass from one contact to the other, then there is a conductor between such pair of contacts that will cause a short. Alternatively, pairs of adjacent contacts residing under different metal combs can be tested in groups at a single time for narrowing the location(s) of shorts between adjacent contacts, and speeding up the present electrical defect testing process at the first metal level. Once contact-to-contact shorts are located, they can then be fixed using known techniques. However, if no current can pass from adjacent contacts, then this pair of contacts is electrically isolated from each other, and no short exists there-between such contacts.

Since the spacings of the shallow trench isolation in the substrate 25, the dual comb gate conductors 32, 34, the metal contacts 70 and the dual metal comb structures 82, 84 can be varied in this test structure, the invention advantageously distinguishes and isolates contact-to-contact shorts from the various other types of electrical defects residing at this level within the IC including, but not limited to, electrical defects between two adjacent metal lines residing above the contacts, electrical defects between two adjacent polysilicon lines residing below the contacts, and the like. As such, the invention allows for the rapid detection of shorts between adjacent contacts early in the integrated circuit (“IC”) fabrication process, thereby avoiding contact-to-contact shorts within the final IC. Also, because numerous contacts can be tested simultaneously, it avoids the time consuming task of having to physically inspect the semiconductor device for conductive lines residing between adjacent contacts, which result in contact-to-contact type shorts.

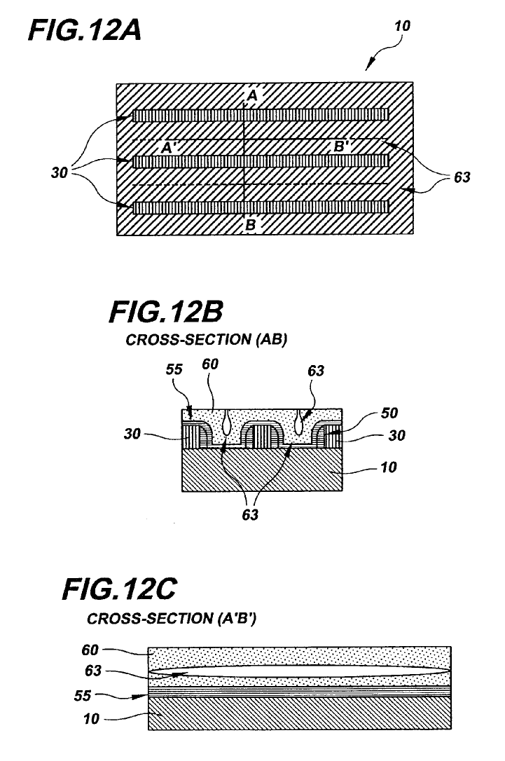

While not deviating from the novel concept of the invention, FIGS. 12A-14C show an alternate embodiment of the invention. In this aspect, isolated gate conductors 30 may be formed directly over the substrate 10. Spacers 50 may then be formed along the gate conductors 30, followed by deposition of a barrier layer, such as a nitride, over the substrate 10. The gate conductors 30 may be formed as straight gate conductors isolated from each other, or as wiggled gate conductors isolated from each other if increased density is required on the end product. As compared to the above embodiment of the invention, the gate conductors of FIGS. 12A-14C are not formed as comb structures, and are therefore, electrically isolated from each other.

A conformal insulating layer is then provided over the structure surface by known techniques to electrically insulate adjacent gate conductors from one another. Preferably, a dielectric layer 60 is provided over the structure surface to conformally coat the structure and electrically isolate adjacent gate conductors. However, it should be appreciated that conventional semiconductor materials may be provided over the surface so long as such semiconductor materials have sufficient insulative properties for electrically isolating adjacent gate conductors from one another.

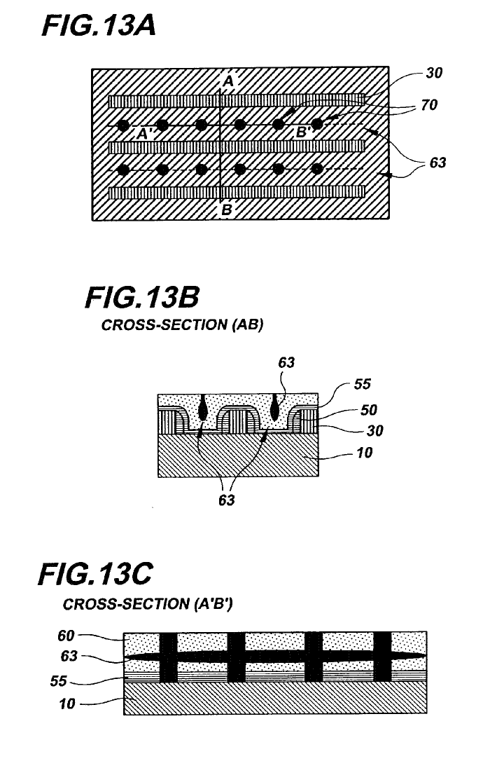

Using dielectric layer 60 as the conformal insulating layer, upon depositing this layer, voids 63 are sometimes formed between adjacent isolated gate conductors 30 within the dielectric layer 60, as is shown in FIGS. 12B and 12C. These voids 63 can be long voids that may run up to an entire length of the gate conductors 30. Once the contact openings are formed in the dielectric layer 60, through the barrier layer 55, down to the substrate layer 10, selected contact openings may traverse through these voids 63 residing between adjacent gate conductors 30. Referring to FIGS. 13A-13C, upon filling the contact openings with metal to form the contacts 70, a metal line may connect adjacent selected contact openings that traverse through the voids, thereby leading to contact-to-contact shorts.

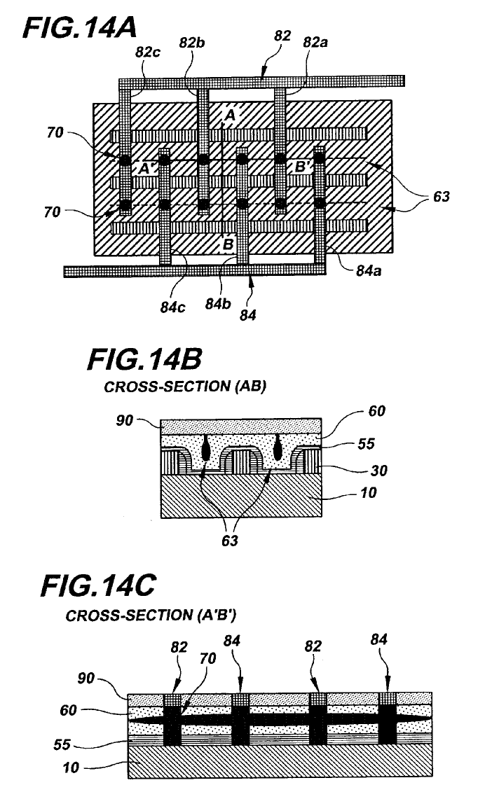

Again, in accordance with the invention, an electrical defect test structure is formed at the first metal level within the device for locating and identifying contact-to-contact shorts early in the development process. Referring to FIGS. 14A-14C, and as discussed above, the first level metal layer is formed as “M1” dual comb metal structures 82, 84 over the dielectric layer 60 in locations over the contacts 70. The “M1” dual comb metal structures 82, 84 reside within a dielectric material 90. As discussed in detail above, the dual comb metal structures 82, 84 may be formed before or after deposition of the dielectric material 90.

The “M1” dual comb metal structures 82, 84 reside on opposite sides of the top surface of the dielectric layer 60. The first metal comb 82 has metal lines 82 a, b, etc. extending there-from that are electrically connected to one another, while the second metal comb 84 has electrically connected metal lines 84 a, b, etc. extending there-from. These metal lines 82 a, b, etc. and 84 a, b, etc. reside substantially perpendicular to the gate conductors 30, such that, a portion of these metal lines overlaps but does not contact a portion of the gate conductors 30, being isolated from the gate conductor by insulator 60.

In accordance with the invention, the metal lines 82 a, b, etc. and 84 a, b, etc. may be straight or wiggled. The extending lines 82 a, b, etc. of metal comb 82 and extending lines 84 a, b, etc. of metal comb 84 are interspaced with each other, and reside over the contacts 70 such that adjacent contacts reside under and are in direct communication with different metal comb structures. That is, adjacent contacts are in electrical communication with different metal comb structures. The “M1” dual comb metal structures 82, 84 may then be used to test for electrical continuity, whereby if an electrical current passes from one metal comb to the other, then this implies that a conductive line connects at least two adjacent contacts residing on the different metal combs, which will ultimately lead to a short.

Thus, the present invention advantageously provides a test structure early in the semiconductor device development stages for identifying and distinguishing contact-to-contact shorts from the various other types of shorts that may reside within the device. The interrelated geometries of the substrate, gate conductors, contacts and “M1” dual comb test structures of the invention enable the monitoring and detection of contact-to-contact shorts within a variety of different materials known for use in the semiconductor fabrication process. The electrical continuity parameters are measurable at the first metal level using the present interlaced metal comb structures. Since the extending lines of the “M1” dual comb test structures reside substantially perpendicular to the gate conductors and overlap at least a portion of the gate conductors, the semiconductor device may be provided with varying gate conductor-to-gate conductor spacing and contact-to-contact spacing, while still being able to detect contact-to-contact shorts within the device.

While the present invention has been particularly described, in conjunction with a specific preferred embodiment, it is evident that many alternatives, modifications and variations will be apparent to those skilled in the art in light of the foregoing description. It is therefore contemplated that the appended claims will embrace any such alternatives, modifications and variations as falling within the true scope and spirit of the present invention.

Thus, having described the invention, what is claimed is:

1. A test structure for testing for electrical continuity between adjacent contacts comprising:
gate conductors within an insulating layer over a substrate layer;
metal contacts within said insulating layer between said gate conductors;
a first metal comb structure having a first set of extending lines in electrical communication with a first set of said metal contacts; and
a second metal comb structure having a second set of extending lines interlaced with said first set of extending lines that are in electrical communication with a second set of said metal contacts,
wherein each metal contact of said first set of metal contacts in communication with said first metal comb structure is adjacent to at least one metal contact of said second set of metal contacts in communication with said second metal comb structure such that an electrical current passing from said first metal comb structure to said second metal comb structure indicates an electrical defect existing between adjacent metal contacts.

2. The test structure of claim 1 wherein said insulating layer comprises a dielectric layer.

3. The test structure of claim 1 wherein said insulating layer comprises a semiconductor layer having sufficient insulating properties for electrically isolating said gate conductors from each other.

4. The test structure of claim 1 wherein said first and second sets of extending lines respectively comprise straight lines extending from said first and second metal comb structures.

5. The test structure of claim 4 wherein said gate conductors comprise straight gates electrically isolated from each other.

6. The test structure of claim 4 wherein said gate conductors comprise wiggled gates electrically isolated from each other.

7. The test structure of claim 4 wherein said gate conductors comprise first and second gate conductor comb structures having interlaced straight extending gate conductor lines.

8. The test structure of claim 4 wherein said gate conductors comprise first and second gate conductor comb structures having interlaced wiggled extending gate conductor lines.

9. The test structure of claim 1 wherein said first and second sets of extending lines respectively comprise wiggled lines extending from said first and second metal comb structures.

10. The test structure of claim 9 wherein said gate conductors comprise straight gates electrically isolated from each other.

11. The test structure of claim 9 wherein said gate conductors comprise wiggled gates electrically isolated from each other.

12. The test structure of claim 9 wherein said gate conductors comprise first and second gate conductor comb structures having interlaced straight extending gate conductor lines.

13. The test structure of claim 9 wherein said gate conductors comprise first and second gate conductor comb structures having interlaced wiggled extending gate conductor lines.

14. A method for detecting electrical defects between adjacent contacts comprising:
providing a substrate layer;
forming gate conductors over said substrate layer;
depositing an insulating layer over said gate conductors and said substrate layer;
providing metal contacts within said insulating layer between said gate conductors;
forming a first metal layer comb structure having a first set of extending lines in electrical communication with a first set of said metal contacts;
forming a second metal layer comb structure having a second set of extending lines in electrical communication with a second set of said metal contacts, said first and second sets of extending lines being interlaced with each other such that each metal contact of said first set of metal contacts is adjacent to at least one metal contact of said second set of metal contacts; and
testing for electrical continuity between said first and second sets of said metal contacts using said first and second metal layer comb structures, whereby detection of an electrical current passing from said first metal layer comb structure to said second metal layer comb structure indicates an electrical defect existing between adjacent contacts.

15. The method of claim 14 wherein said first and second sets of extending lines respectively comprise straight lines extending from said first and second metal layer comb structures.

16. The method of claim 15 wherein said gate conductors are selected from the group consisting of straight gates electrically isolated from each other, wiggled gates electrically isolated from each other, and combinations thereof.

17. The method of claim 15 wherein said gate conductors are selected from the group consisting of first and second gate conductor comb structures having interlaced straight extending gate conductor lines, first and second gate conductor comb structures having interlaced wiggled extending gate conductor lines, and combinations thereof.

18. The method of claim 14 wherein said first and second sets of extending lines respectively comprise wiggled lines extending from said first and second metal comb structures.

19. The method of claim 18 wherein said gate conductors are selected from the group consisting of straight gates electrically isolated from each other, wiggled gates electrically isolated from each other, and combinations thereof.

20. The method of claim 18 wherein said gate conductors are selected from the group consisting of first and second gate conductor comb structures having interlaced straight extending gate conductor lines, first and second gate conductor comb structures having interlaced wiggled extending gate conductor lines, and combinations thereof.
